(19) United States
(12) Patent Application Publication
(10) Pub. No.: US 2018/0218926 A1
(43) Pub. Date: Aug. 2, 2018

(54) ACTIVE THERMAL CONTROL HEAD HAVING ACTUATABLE COLD CAPACITOR

(71) Applicant: Delta Design, Inc., Poway, CA (US)

(72) Inventors: Larry Stuckey, Poway, CA (US); Jerry Ihor Tustaniwskyj, Mission Viejo, CA (US); Samer Kabbani, Encinitas, CA (US)

(73) Assignee: Delta Design, Inc., Poway, CA (US)

(21) Appl. No.: 15/879,154

(22) Filed: Jan. 24, 2018

Related U.S. Application Data
(60) Provisional application No. 62/452,655, filed on Jan. 31, 2017.

(51) Int. Cl. H01L 21/67; G01R 31/00

(52) U.S. Cl. CPC H01L 21/67103; G01R 31/003

(57) ABSTRACT

A thermal control head for a semiconductor device handler includes: a heater configured to heat a semiconductor device; a cold manifold; and a cooling mass that is movable between: a first position at which a first surface of the cooling mass contacts a surface of the cold manifold, and a second position at which the first surface of the cooling mass is separated from the cold manifold, and a second surface of the cooling mass contacts a surface of the heater.

### CROSS-REFERENCE TO RELATED APPLICATIONS

The present application claims priority to U.S. Provisional Appl. No. 62/452,655, filed on Jan. 31, 2017, the contents of which are hereby incorporated by reference in their entirety.

### BACKGROUND

The present application relates to handlers for electronic devices, such as semiconductor devices and integrated circuit (IC) devices.

Device handlers are used to perform testing on electronic devices. A convection temperature chamber is often used to thermally condition devices under test (DUTs) prior to electronic testing. Temperature set points range, for example, from −60° C. up to 175° C. Temperature chambers are large, costly, inefficient, require significant time and energy to change temperature and require up to 3 minutes of thermal soak time for the DUTs to come to the test temperature set point.

It is typically an hour or more to convert from one set point temperature to another within a temperature chamber. Due to this, it is a typical procedure to dedicate handlers to run at specific set point temperatures (hot or cold). This requires multiple handlers, multiple change kits (to convert handlers to test different DUTs), and multiple electronic contactors (test sockets). The need for multiple handlers can also result in scheduling problems and compromise lot integrity.

The use of temperature chambers also requires that all mechanisms that transport DUTs be at or above the hot set point temperatures and at or below the cold set point temperatures. This drives the use of exotic and costly materials, components, fluids and lubrication.

The temperature extremes also cause thermal expansion, which can result in mechanism inaccuracies and jams. Different thermal expansion in different materials can also lead to warpage induced wear and additional jams.

An hour or more is typically required to return a temperature chamber back to ambient temperature to correct a jam or fix a failed component. After completion, it takes another hour to return the temperature chamber back to the testing temperature. For extreme cold temperature testing, this problem may be exacerbated by condensation or frosting of components. In this case, the temperature in the chamber must be brought high enough to melt the frost and dry the chamber, and then cooled to set point temperature.

Some chamber-less handlers solve many of these problems. For example, handlers sometimes include active thermal control (ATC), in which a DUT is quickly heated or cooled to a predetermined set point temperature while in the handler, prior to performing electronic testing. For example, Joule heating, sometimes called resistive heating or ohmic heating, is used in many ATC solutions for hot test set point control. When Joule heating is used, a high difference between a target set point temperature of the DUT and a current temperature of the DUT (termed the “hot temperature offset”) is not a significant barrier to performing hot testing, because applying additional power to a heater will quickly increase the heater's temperature independent of its present temperature. The heating rate is proportional to the amount of power applied to the heater.

However, it is more difficult to quickly lower the temperature of the DUT for cold testing, because there is no equivalent to Joule heating when lowering the DUT temperature. For decreasing the temperature of a DUT, the cooling rate is proportional to the difference in temperature between the DUT and the cold source. If the difference between the cold source temperature and the DUT temperature is not high enough, the DUT cannot be cooled quickly.

U.S. Pat. No. 5,821,505 (“the '505 patent”), which is assigned the same assignee as the present application and is hereby incorporated by reference in its entirety, describes systems that use a very low temperature cold source (a heat sink cooled by a liquid coolant) to maximize the amount of heat that can be absorbed by the cold source.

The system described in the '505 patent is capable of quickly reacting to large variations in power dissipation within an electronic device and thereby maintains the device temperature near a constant set point temperature while the device is being tested. However, one issue that may arise when using a cold source in the form of a very low temperature heat sink that is in permanent contact with a heater is that the heater must continually overcome the removal of heat via the heat sink.

### SUMMARY OF THE INVENTION

The present disclosure describes systems that provide increased DUT cooling rates by using a cold thermal mass that can quickly absorb heat.

The cooling mass (or “cold capacitor”) is configured to change the DUT temperature to a desired cold set point. After that point is reached, the minimal steady state energy transfer will take over, limiting the required heater power needed to maintain set point.

For single insertion use (that is, in testing where DUT hot testing and DUT cold testing are performed one after the other on the same handler), the cold thermal mass is charged during the hot test. Following the hot test, in order to quickly “cold soak” the DUT, the cold thermal mass is brought into thermal conductive contact with the device, such that the cold thermal mass can quickly absorb heat from the DUT.

In one embodiment, a thermal control head for a semiconductor device handler includes: a heater configured to heat a semiconductor device; a cold manifold; and a cooling mass that is movable between: a first position at which a first surface of the cooling mass contacts a surface of the cold manifold, and a second position at which the first surface of the cooling mass is separated from the cold manifold, and a second surface of the cooling mass contacts a surface of the heater.

In one aspect, the cold manifold comprises a cold manifold plate and a gimbal piece that is separate from the cold manifold plate, and when the cooling mass is in the first position, said surface of the cooling mass contacts a surface of the gimbal piece.

In one aspect, which is combinable with any of the above embodiments and aspects, the thermal control head further includes a thermally conductive compliant link located between the cooling mass and the gimbal piece.

In one aspect, which is combinable with any of the above embodiments and aspects, the thermally conductive compliant link is an annular coil.

In one aspect, which is combinable with any of the above embodiments and aspects, the annular coil is disposed in a groove that extends around the gimbal piece.

In one aspect, which is combinable with any of the above embodiments and aspects, at least a portion of the gimbal piece is located in a recess in a first side of the cooling mass.

In one aspect, which is combinable with any of the above embodiments and aspects, the thermal control head further includes a gimbal spring configured to hold a second surface of the gimbal piece against a surface of the cold manifold plate.

In one aspect, which is combinable with any of the above embodiments and aspects, the thermal control head further includes: a heater holding plate attached to the heater in a sealed manner; a bellows assembly that surrounds the cooling mass, wherein a first end of the bellows assembly is attached to a first end of the cooling mass in a sealed manner, a second end of the bellows assembly is attached to the heater holding plate in a sealed manner, and a first chamber is located in the bellows assembly; an enclosure that surrounds a portion of the bellows assembly, wherein a second chamber is formed between the bellows assembly and the enclosure; and a gas manifold comprising a first port leading to the first chamber, and a second port leading to the second chamber. The gas manifold is configured to provide pressurized gas to the first chamber via the first port and to provide pressurized gas to the second chamber via the second port. When the gas manifold provides pressurized gas to the first chamber, the cooling mass moves to the first position and the pressurized gas in the first chamber causes the second end of the bellows assembly to press the heater holding plate. When the gas manifold provides pressurized gas to the second chamber, the cooling mass moves to the second position.

In one aspect, which is combinable with any of the above embodiments and aspects, a first end of the enclosure is attached to the cold manifold in a sealed manner, and a second end of the enclosure is attached to the gas manifold in a sealed manner.

In another embodiment, a system includes: the thermal control head of claim 1; and a pusher assembly comprising: at least one plate fixed to a stationary base, a pusher holding plate fixed to the at least one plate, and a pusher extending through the pusher holding plate and configured to move relative to the pusher holding plate. A first surface of the pusher is configured to be contacted by the heater. A second surface of the pusher is configured to contact a semiconductor device under test.

In another embodiment, a method of controlling a temperature of a semiconductor device using thermal control head includes: providing a thermal control head including: a heater configured to heat a semiconductor device, a cold manifold, and a cooling mass that is movable between: a first position at which a first surface of the cooling mass contacts a surface of the cold manifold, and a second position at which the first surface of the cooling mass is separated from the cold manifold, and a second surface of the cooling mass contacts a surface of the heater; moving the cooling mass to the first position, and while the cooling mass is at the first position: heating the semiconductor device using the heater, and cooling the cooling mass using the cold manifold; and moving the cooling mass to the second position, and while the cooling mass is at the second position: cooling the semiconductor device using the cooling mass, via the heater.

In one aspect, the cold manifold comprises a cold manifold plate and a gimbal piece that is separate from the cold manifold plate, and when the cooling mass is in the first position, said surface of the cooling mass contacts a surface of the gimbal piece.

In one aspect, which is combinable with any of the above embodiments and aspects, the thermal control head further comprises a thermally conductive compliant link located between the cooling mass and the gimbal piece.

In one aspect, which is combinable with any of the above embodiments and aspects, the thermally conductive compliant link is an annular coil.

In one aspect, which is combinable with any of the above embodiments and aspects, the annular coil is disposed in a groove that extends around the gimbal piece.

In one aspect, which is combinable with any of the above embodiments and aspects, at least a portion of the gimbal piece is located in a recess in a first side of the cooling mass.

In one aspect, which is combinable with any of the above embodiments and aspects, the thermal control head further comprises a gimbal spring configured to hold a second surface of the gimbal piece against a surface of the cold manifold plate.

In one aspect, which is combinable with any of the above embodiments and aspects, the thermal control head further comprises: a heater holding plate attached to the heater in a sealed manner; a bellows assembly that surrounds the cooling mass, wherein a first end of the bellows assembly is attached to a first end of the cooling mass in a sealed manner, a second end of the bellows assembly is attached to the heater holding plate in a sealed manner, and a first chamber is located in the bellows assembly, an enclosure that surrounds a portion of the bellows assembly, wherein a second chamber is formed between the bellows assembly and the enclosure, and a gas manifold comprising a first port leading to the first chamber, and a second port leading to the second chamber. The gas manifold is configured to provide pressurized gas to the first chamber via the first port and to provide pressurized gas to the second chamber via the second port. The cooling mass is moved to the first position by providing pressurized gas to the first chamber using the gas manifold, and while the cooling mass is in the first position, the pressurized gas in the first chamber causes the second end of the bellows assembly to press the heater holding plate. The cooling mass is moved to the second position by providing pressurized gas to the second chamber using the gas manifold.

In one aspect, which is combinable with any of the above embodiments and aspects, a first end of the enclosure is attached to the cold manifold in a sealed manner, and a second end of the enclosure is attached to the gas manifold in a sealed manner.

In one aspect, which is combinable with any of the above embodiments and aspects, the method further includes: providing a pusher assembly comprising: at least one plate fixed to a stationary base, a pusher holding plate fixed to the at least one plate, and a pusher extending through the pusher holding plate and configured to move relative to the pusher holding plate, contacting a first surface of the pusher with the heater, and contacting a semiconductor device under test with a second surface of the pusher.

### BRIEF DESCRIPTION OF THE DRAWINGS

FIG. 1 is a perspective view of a portion of a thermal head including a heater, a heater holding plate, a seal, and a bellows assembly.

FIG. 2A is a sectional perspective view of the heater, holding plate, and seal shown in FIG. 1.

FIG. 2B is a sectional perspective view of the bellows assembly shown in FIG. 1.

FIG. 2C is a sectional perspective view of a cooling mass, compliant link, gimbal piece, and spring of the thermal head.

FIG. 3 is a sectional perspective view of the thermal head shown in FIG. 1.

FIG. 4A is a perspective view of a thermal head along with a gas manifold, a cold manifold, and an enclosure located between the gas manifold and the cold manifold.

FIG. 4B is a sectional perspective view of the thermal head, gas manifold, cold manifold, and enclosure shown in FIG. 4A.

FIG. 4C is a front view of the thermal head, gas manifold, cold manifold, and enclosure shown in FIG. 4A.

FIG. 4D is a front sectional view of the thermal head, gas manifold, cold manifold, and enclosure shown in FIG. 4A.

FIG. 5A is a perspective view of a pusher assembly and stationary base for use with the thermal head of FIG. 1.

FIG. 5B is a front sectional view of the pusher assembly shown in FIG. 5A.

FIG. 5C is a perspective view of the pusher assembly shown in FIG. 5A.

FIG. 6 is a perspective view of a portion of the thermal head shown in FIG. 1 interfacing with a portion of the pusher assembly.

FIG. 7 is a perspective view showing the heater of the thermal head interfacing with a pusher of the pusher assembly, during a hot soak process.

FIG. 8 is a sectional perspective view of the cooling mass and gimbal piece of the thermal head interfacing with the cold manifold, during draining of heat from the cooling mass.

FIG. 9 is a sectional perspective view of the cooling mass of the thermal head interfacing with the heater of the thermal head during a cold soak process.

FIG. 10 is a sectional perspective view of the cooling mass being separated from the gimbal piece during a cold soak process.

FIG. 11 is a diagram schematically showing a cold test followed by a hot test, when using a thermal head of one embodiment of the invention.

FIG. 12A-12E are graphs showing DUT Temperature vs. time when using a thermal head of one embodiment of the invention, during a cold soak process (FIG. 12A), steady state at −10° C. (FIG. 12B), a hot soak process (FIG. 12C), steady state at 90° C. (FIG. 12D), and steady state at 125° C. (FIG. 12E).

FIGS. 13 and 14 are diagrams schematically illustrating a convention handler material flow.

FIGS. 15 and 16 are diagraphs schematically illustrating a material flow when using a handler equipped with a thermal head with a cold capacitor according to an embodiment of the present invention.

FIG. 17 is a perspective view of an array of thermal heads according to one embodiment of the invention.

### DETAILED DESCRIPTION

The present disclosure is capable of embodiments in many different forms. While certain embodiments are described below and shown in the drawings, the present disclosure is to be considered exemplary of the principles of the invention and is not intended to limit the broad aspects of the invention to the embodiments illustrated and described.

Embodiments of the present invention allow for single insertion multiple temperature testing with rapid set point temperature changes (for example, under 10 seconds) and a full range of temperature extremes.

The extremely large thermal mass of the temperature chamber can be eliminated, so that the thermal mass that is brought to temperature is greatly reduced to that of only the DUT and the small thermal components that contact it.

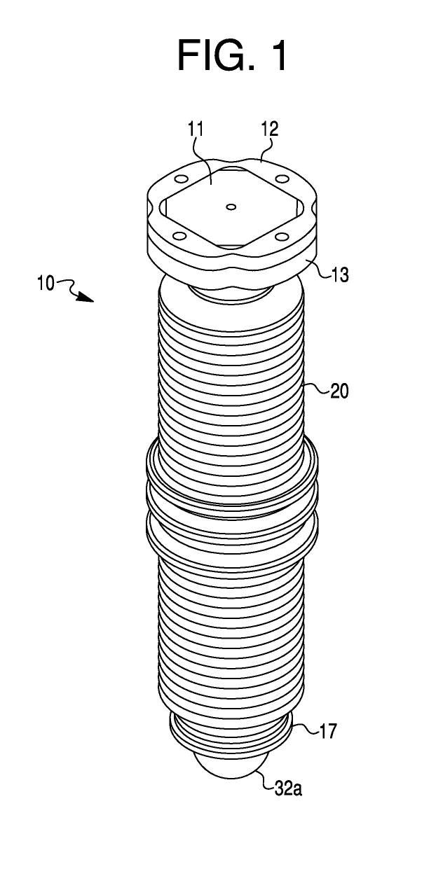

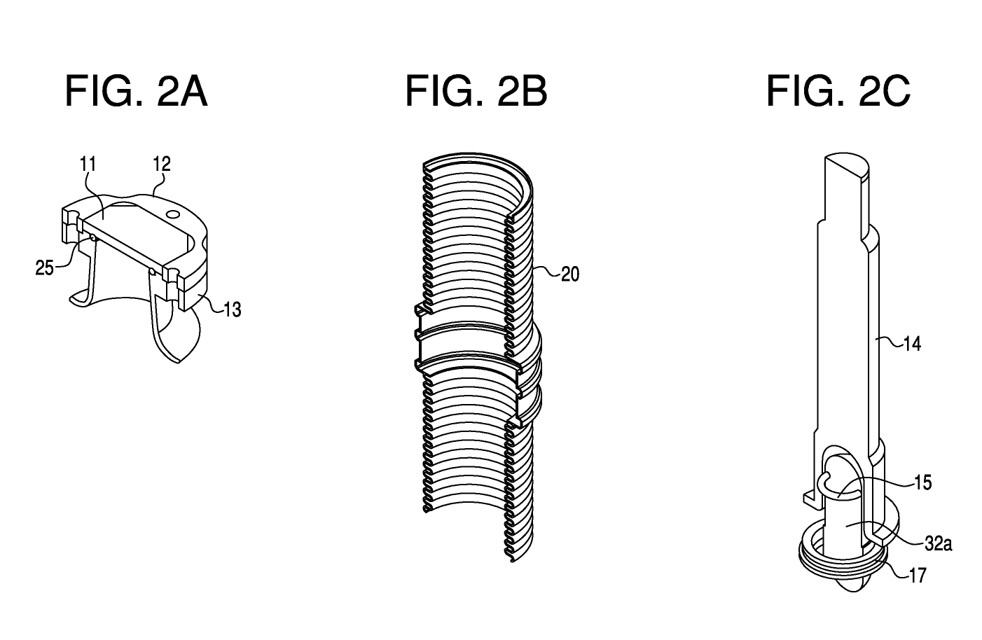

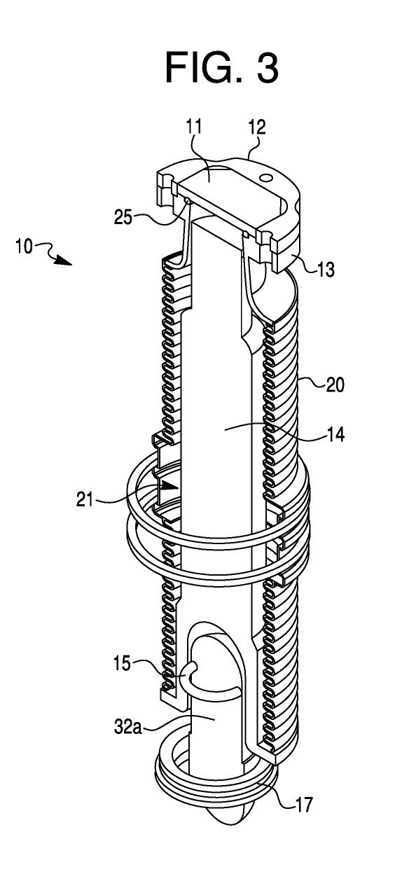

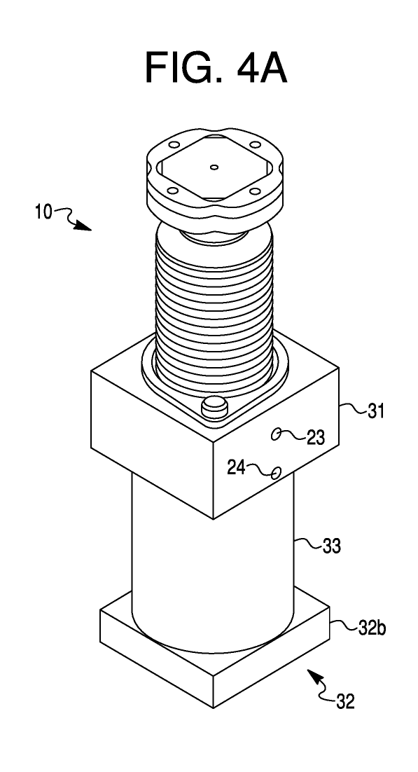

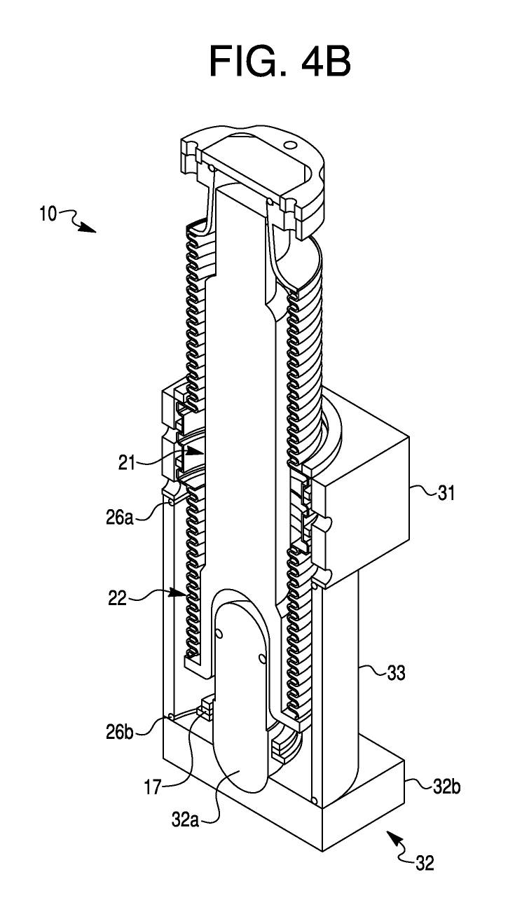

FIG. 1 is a perspective view of a portion of a thermal control head 10 including a heater 11, an upper heater holding plate 12, a lower heater holding plate 13, a seal 25 (such as an O-ring), a bellows assembly 20, a gimbal piece 32a, and a spring 17. FIG. 2A is a sectional perspective view of the heater 11, upper heater holding plate 12, lower heater holding plate 13, and seal 25. FIG. 2B is a sectional perspective view of the bellows assembly 20 shown in FIG. 1. FIG. 2C is a sectional perspective view of a cooling mass 14, a compliant link 15, the gimbal piece 32a, and the spring 17 of the thermal head 10. FIG. 3 is a sectional perspective view of the thermal head 10 shown in FIG. 1.

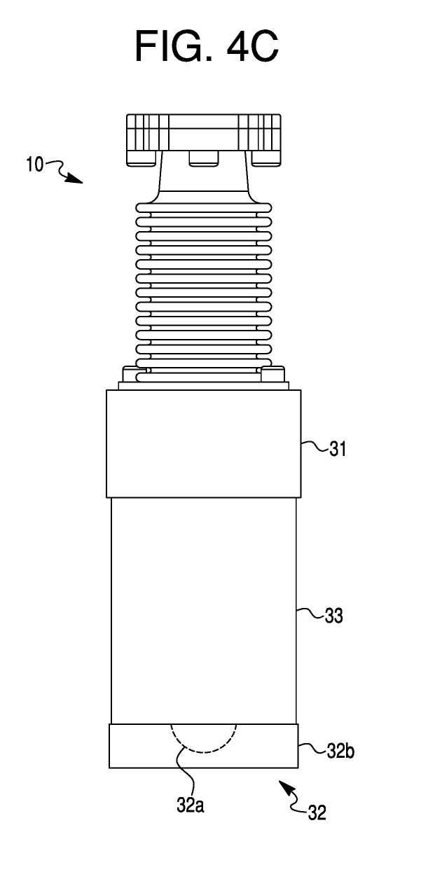

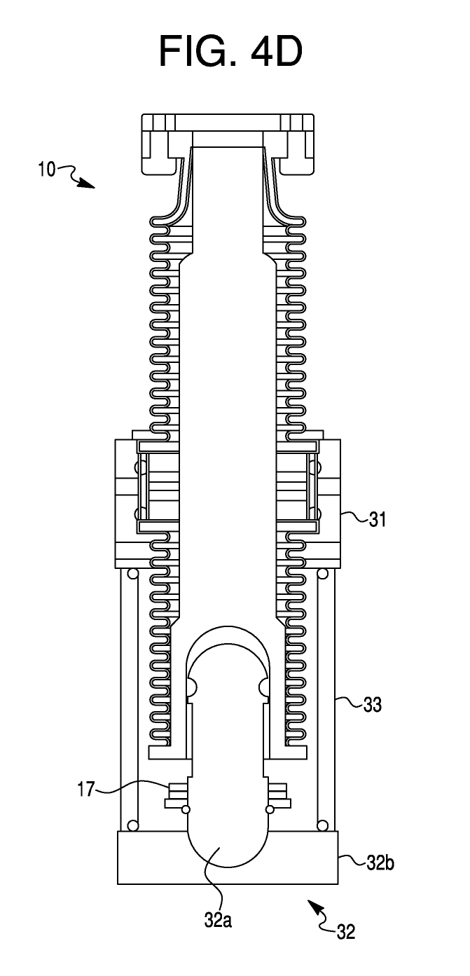

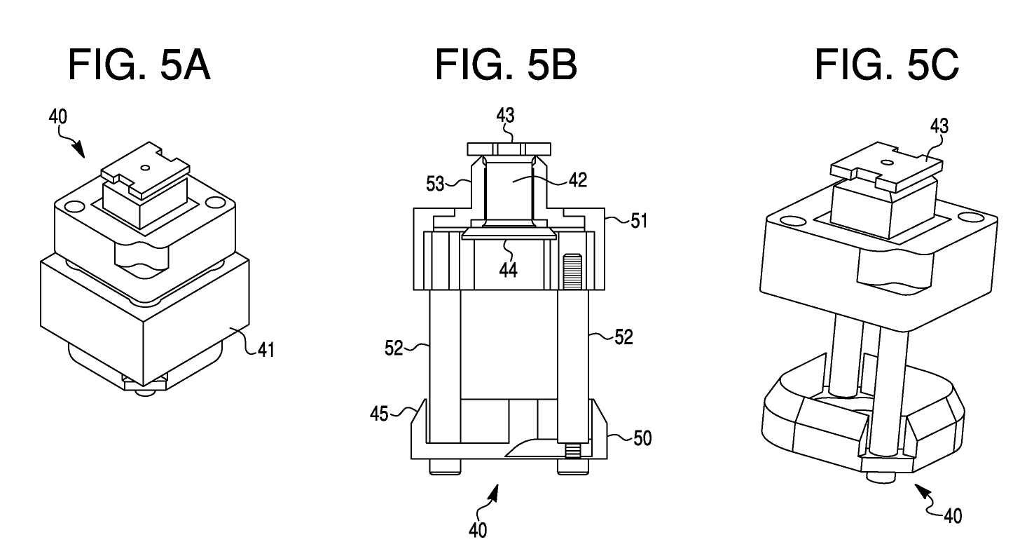

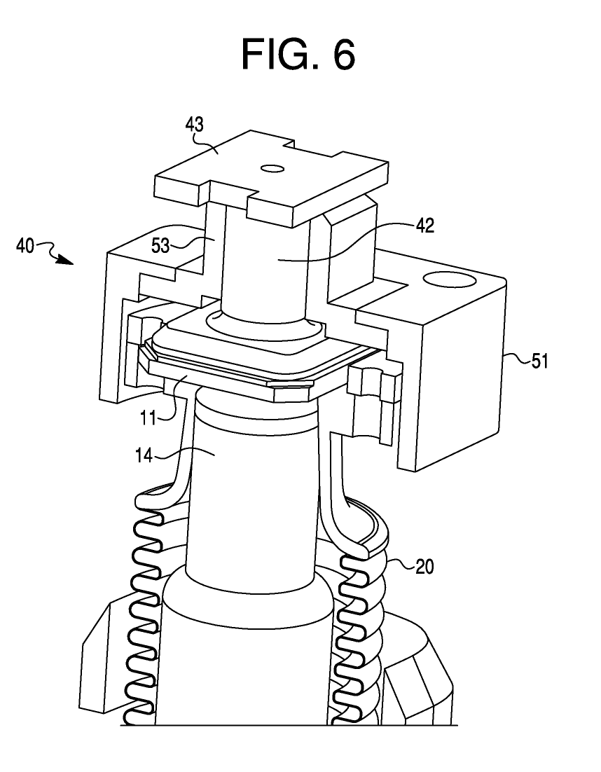

FIG. 4A is a perspective view of the thermal contact head 10, showing a gas manifold 31, a cold manifold 32, and an enclosure 33 located between the gas manifold 31 and the cold manifold 32. FIG. 4B is a sectional perspective view of the thermal head 10, gas manifold 31, cold manifold 32, and enclosure 33 shown in FIG. 4A. FIG. 4C is a front view of the thermal head 10, gas manifold, cold manifold, and enclosure shown in FIG. 4A. FIG. 4D is a front sectional view of the thermal head 10, gas manifold 31, cold manifold 32, and enclosure 33 shown in FIG. 4A.

The upper and lower heater holding plates 12, 13 are attached to the heater 11. The heater 11 has a recessed step in each corner that allows clamping with the heat holding plates 12, 13 to sandwich the heater 11 with the O-ring 25 without protruding past the surface of the heater 11. Screws clamp the upper and lower holding plates 12, 13 together.) The seal 25 is located between the lower heater holding plate 13 and the heater 11. The seal 25 may be made of, for example, silicone rubber.

The gas manifold 31 and the cold manifold 32 are fixed to the device handler in which the thermal control head is integrated. A center portion of the bellows assembly 20 is fixed to the gas manifold 31. A first, inner chamber 21 is located inside the bellows assembly 20. The arrows 21 and 22 appear to be point to the cold mass and bellows, respectively. Can they be moved to show the cavity? The enclosure 33 is fixed to both the gas manifold 31 and the cold manifold 32, for example, by sandwiching the enclosure 33 between the air manifold 31 and the cold manifold 32 with bolts and compressing the O-rings 26a, 26b. Thus, a second, outer chamber 22 is formed between the bellows assembly 20 and the enclosure 33. Seals 26a, 26b (e.g., O-rings) are respectively located between the enclosure 33 and the gas manifold 31, and between the enclosure 33 and the cold manifold 32. The seals 26a, 26b may be made of, for example, silicone rubber. The cold manifold 32 includes the gimbal piece 32a and a cold manifold plate 32b, as shown in FIGS. 4B-4D. A gimbal spring 17 is attached to the gimbal piece 32a, and is also attached to the enclosure 33 or to the cold manifold plate 32b. The gimbal spring 17 is configured to press the gimbal piece 32a against the cold manifold plate 32b. The gimbal piece may be made of, for example, Ni-plated copper.

The gas manifold 31 includes a first port 23 leading to the inner chamber 21, and a second port 24 leading to the outer chamber 22. The gas manifold 31 is configured to provide pressurized gas (e.g., N₂ or air, such as CDA (clean dry air)) to the inner chamber 21 via the first port 23 and to provide pressured gas to the outer chamber 22 via the second port 24.

A bottom side of the cooling mass 14 is attached (e.g., by soldering) to a bottom side of the bellows assembly 20, so that when the bottom of the bellows assembly 20 move upward or downward, the cooling mass 14 moves with the bottom of the bellows assembly 20. The gimbal piece 32a is located in a recess in a bottom of the cooling mass 14. The compliant link 15 is located between the gimbal piece 32a and the cooling mass 14. The compliant link 15 is an annular coil, and fits in a groove formed around the gimbal piece 32a. The cooling mass 14 and the compliant link 15 may are made of a thermally conductive material, such as copper.

A lower side of the lower heater holding plate 13 is attached (e.g., by soldering) to a top side of the bellows assembly, so that when the top side of the bellows assembly moves upward or downward, the lower heater holding plate 13, and thus the upper heater holding plate 12 and heater 11, moves with the top of the bellows assembly 20. The upper and lower heater holding plates 12, 13 may be made of, for example, stainless steel. The bellows assembly 20 may be made of, for example, nickel or a nickel alloy. In other embodiments, only a single heater holder plate may be used.

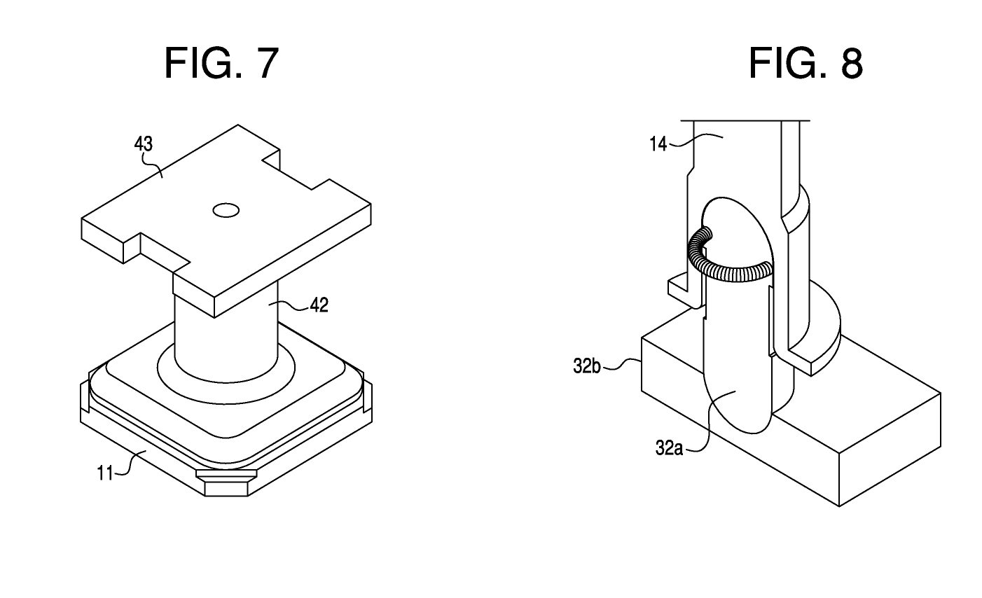

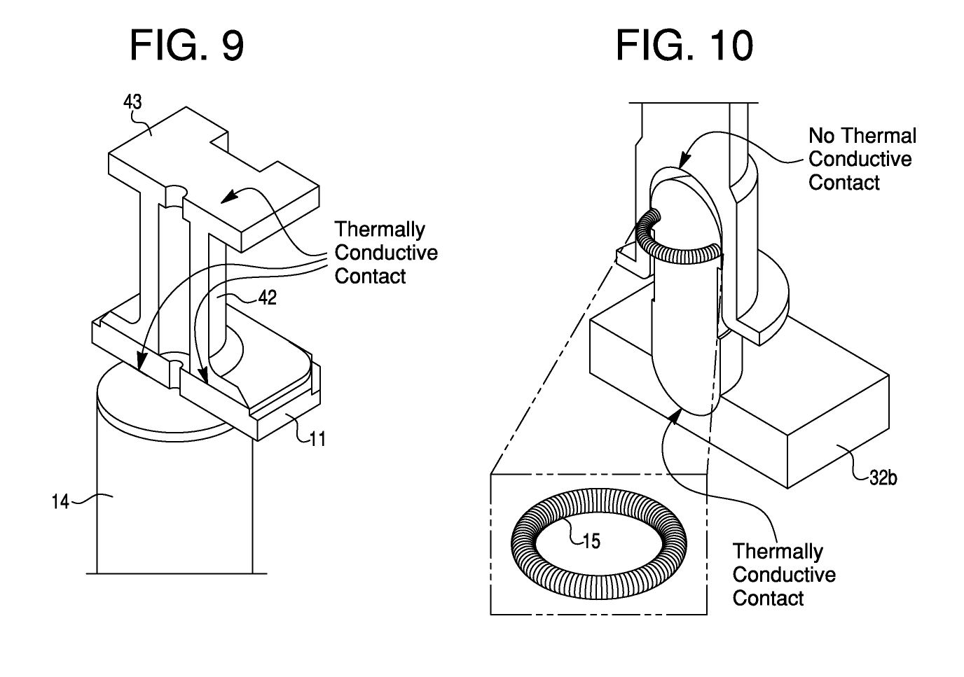

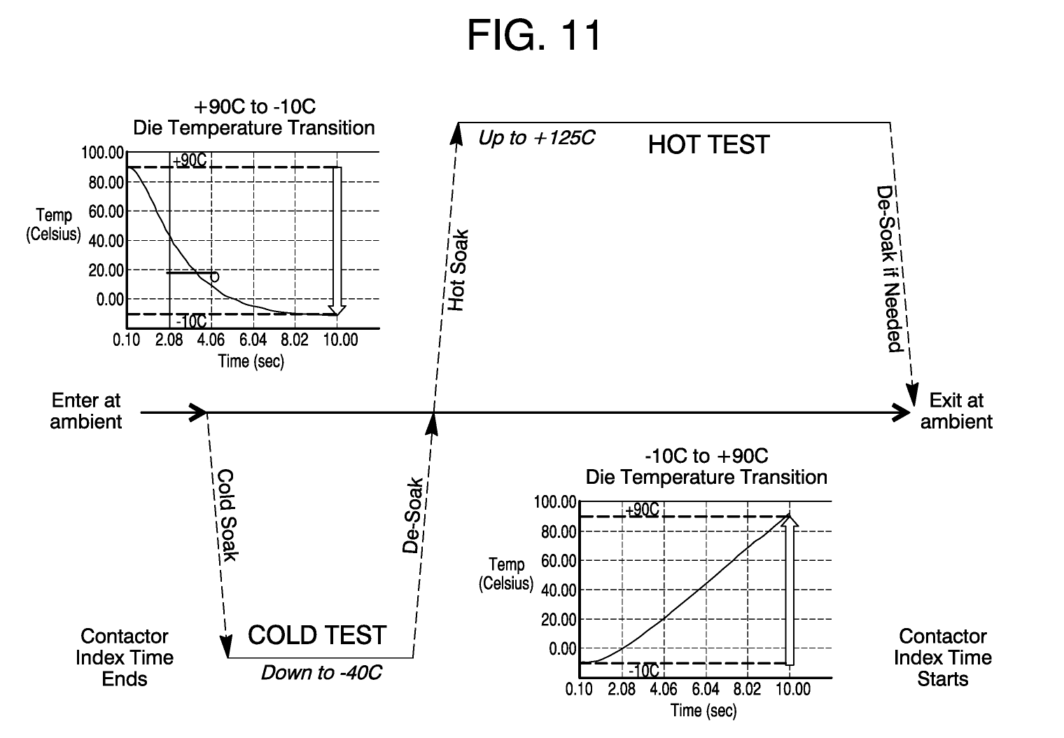

FIG. 5A is a perspective view of a pusher assembly 40 and stationary base 41 which may be used with the thermal head 10 of FIG. 1. FIG. 5B is a front sectional view of the pusher assembly 40 shown in FIG. 5A. FIG. 5C is a perspective view of the pusher assembly 40 shown in FIG. 5A.

The pusher assembly 40 is a kit that is specifically designed for use with a particular DUT type. The stationary base 41 is fixed to the device handler in which the thermal head is located. The pusher assembly 40 includes a first plate 50, a second plate 51 attached to the first plate 50, and a plurality of enclosures 52 separating the first plate 50 from the second plate 51. The pusher assembly also includes a pusher holding plate 53 attached to the second plate, and a thermally conductive pusher 42 extending through the pusher holding plate 53. The pusher 42 has a DUT contact surface 43 and a heater contact surface 44. The first plate 50 includes alignment chamfers 45 that align the first plate 50 to the stationary base 41. The pusher 42 is configured to move with respect to the pusher holding plate 53. Thus, when the heater 11 of the thermal head 10 contacts the heater contact surface 44, the pusher 42 can move upward to apply a contact force against the DUT. The pusher 42 is also able to gimbal within the pusher holding plate 53, so allow for self-alignment with the DUT. The stationary base 41 may have a plurality of gimbaling pusher assemblies attached thereto. For example, hundreds of gimbaling pusher assemblies 40 may be attached to a single base 41, each of the pusher assemblies 40 corresponding to thermal head 10. In other embodiments, the thermal head 10 may be used without a gimballing pusher assembly 40.

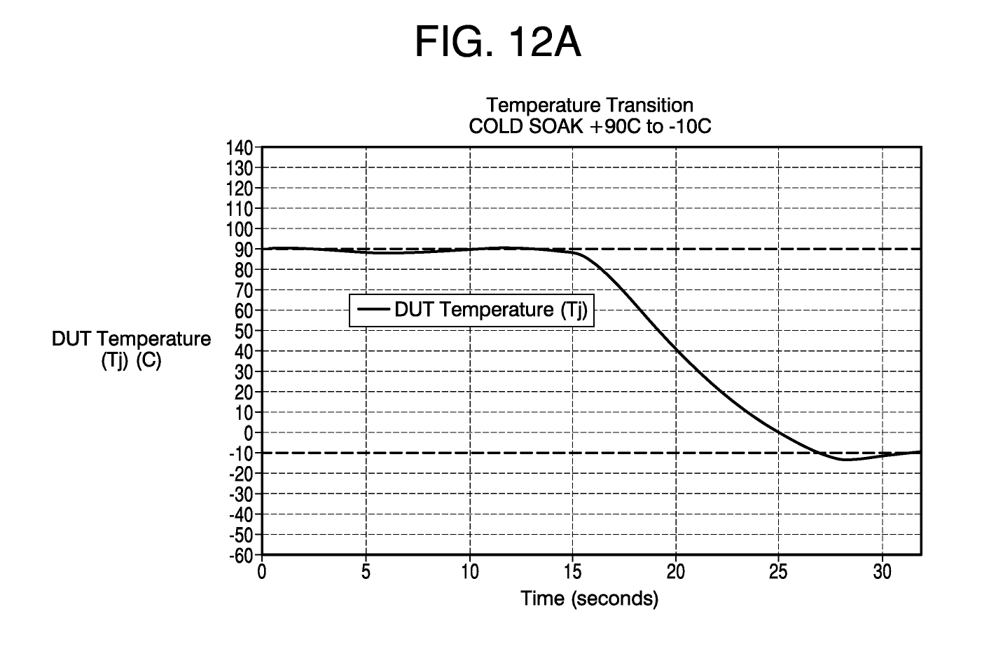

FIG. 6 is a perspective view of a portion of the thermal head 10 shown in FIGS. 1-4 interfacing with a portion of the pusher assembly 40.

The heater 11 is used to perform hot temperature soaking and maintain a hot DUT temperature set point. The hot DUT temperature set point may be in a range of 25° C. to 175° C., or in a range of 50° C. to 150° C., or in a range of 75° C. to 125° C. The heater 11 has a high watt density (for example, in a range of 20 W/cm² to 2000 W/cm², and in a range of 20 W/cm² to 800 W/cm², and more preferably about 25 W/cm²) and low thermal mass (for example, in a range of 0.1 J/° C. to 4 J/° C., preferably 0.3 J/° C. to 0.5 J/° C.). The heater 11 may be made of, for example, aluminum nitride.

The cooling mass 14 is configured to be movable between a first position, at which a lower surface of the cooling mass 14 contacts a surface of the gimbal piece 32a, and a second position, at which an upper surface of the cooling mass contacts a surface of the heater 11. Thus, the cooling mass 14 can be actuated to separate it from the heater 11 during the hot soak and hot test processes, and make it thermally independent of the heater 11 so as to eliminate its thermal mass from burdening the hot processes. The cooling mass 14 is cooled to a temperature much lower than that of the pending cold set point testing temperature. This cooling is completed during the hot soak and hot testing processes, by thermal conduction caused by actuating the cooling mass 14 to be in conductive thermal contact with a cold manifold 32 (e.g., a gimbal piece 32a of the cold manifold 32). The cooling mass 14 is the thermal analogue of an electrical capacitor. The cooling mass 14 is cooled to a low temperature, for example, between −40 and −180° C., and preferably between −80 and −140° C., and more preferably between −100 and −140° C. Thus, the cooling mass 14 can quickly absorb large quantities of heat from the heater 11 when the cooling mass 14 is actuated to be in thermal contact with the heater 11. This accelerates the transition to the cold DUT set point temperature. The cold DUT set point temperature may be in a range of −70° C. to 20° C., or in a range of −40° C. to 10° C., or in a range of −10° C. to 0° C.

The process of actuating the cooling mass 14 between the first and second positions is as follows.

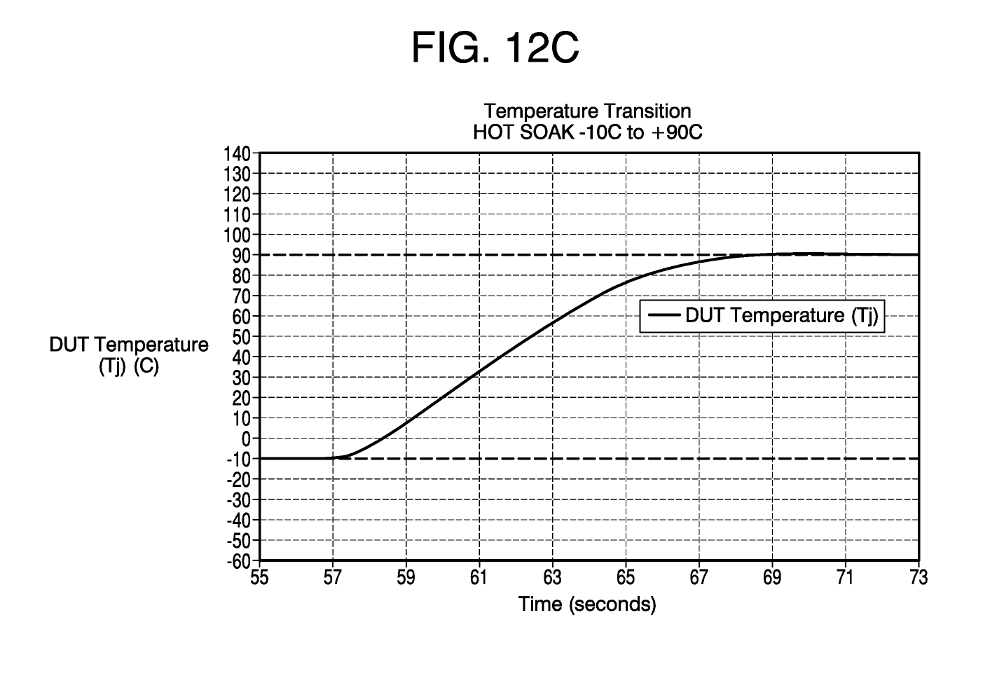

FIG. 6 is a perspective view showing the heater of the thermal head 10 interfacing with a pusher 42 of the pusher assembly 40, during a hot soak process. FIG. 8 is a sectional perspective view of the cooling mass 14 and gimbal piece 32a of the cold manifold 32 interfacing with the cooling mass 14, during cold thermal charging of the cooling mass 14. During hot temperature soaking of a DUT (that is, when the heater 11 is being used to heat a DUT to a high set point temperature), the gas manifold 31 provides pressurized gas into the inner chamber 21. The increased pressure in the inner chamber 21 causes the bellows assembly 20 to expand. The lower end of the bellows assembly 20 is attached to the lower end of the cooling mass 14 in a sealed manner, and the upper end of the bellows assembly 20 is attached to the lower heater holder plate 13 in a sealed manner. Thus, when the bellows assembly 20 expands, the cooling mass 14 moves downward to the first position, at which the cooling mass 14 contacts the cold manifold 32, and more specifically, the gimbal piece 32a of the cold manifold 32, as shown in FIG. 8. Because the cooling mass 14 contacts the cold manifold 32, heat is absorbed from the cooling mass 14 by the cold manifold 32, so that the cooling mass 14 becomes cold (i.e., the cooling mass 14 is “charged”). At the same time, the lower heater holding plate 13, and thus the heater 11, is pressed upward by the top of the bellows assembly 20. This upward pressure presses the heater 11 against the DUT (either directly or via a thermally conductive pusher, described below). This upward pressure also supplies the contactor force to press the DUT into the electrical contacts of a contactor socket. This force may be varied by controlling the pressure in the inner chamber 21 of the bellows assembly 20.

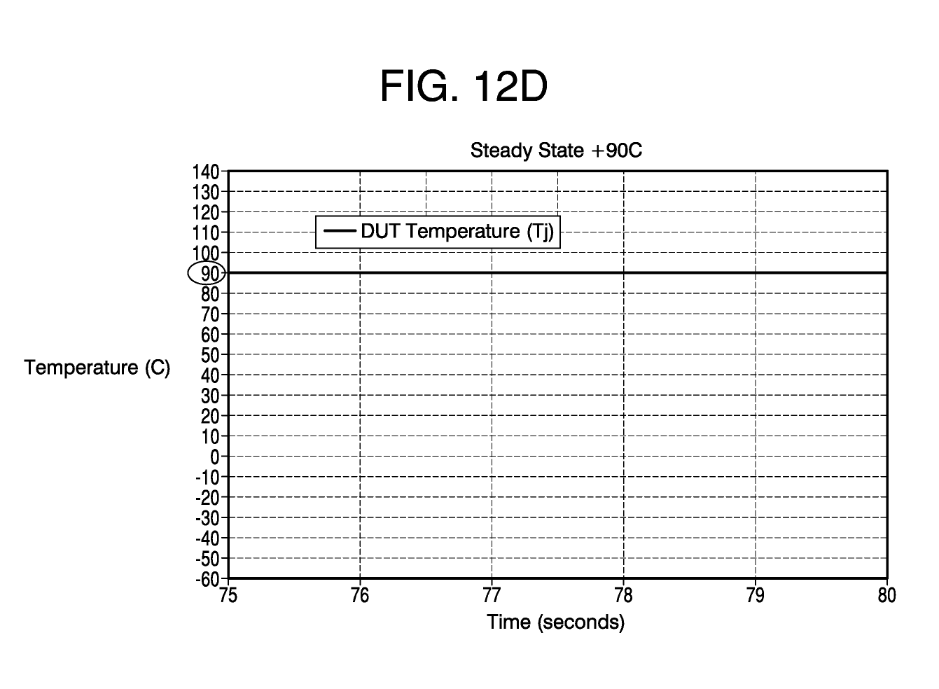

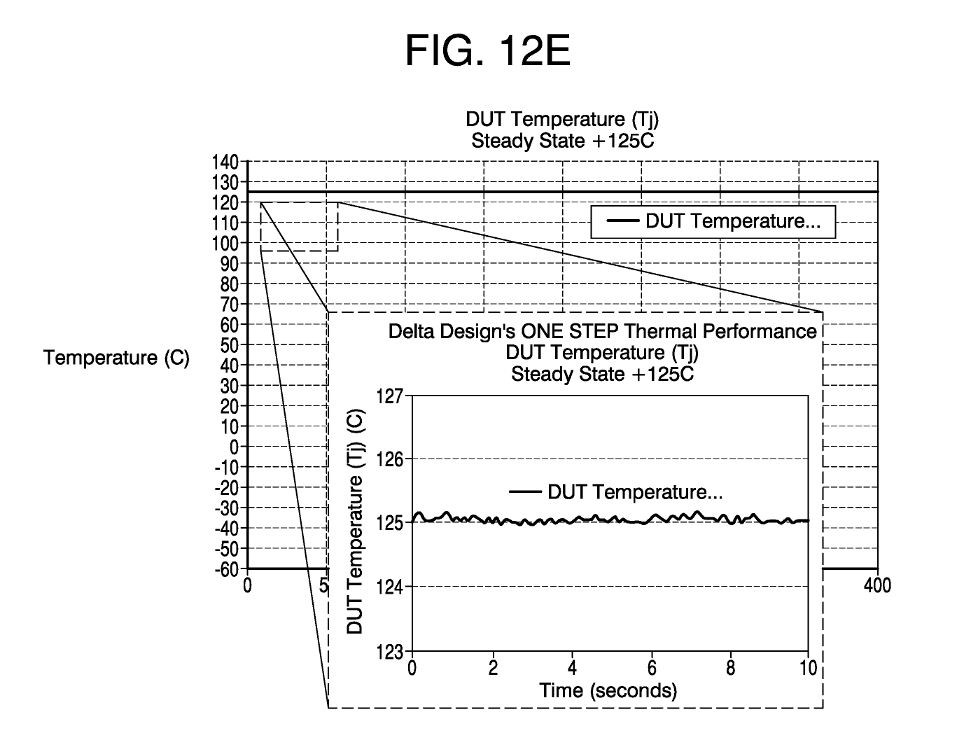

FIG. 9 is a sectional perspective view of the cooling mass 14 of the thermal head 10 interfacing with the heater 11 of the thermal head 10 during a cold soak process. FIG. 10 is a sectional perspective view of the cooling mass 14 being separated from the cold manifold 32 (e.g., the gimbal piece 32a) during a cold soak process. During cold temperature soaking of a DUT (that is, when the thermal head is being used to cool the DUT to a low set point temperature), the gas manifold 31 provides pressurized gas into the outer chamber 22. The increased pressure in the outer chamber 22 causes the lower portion of the bellows assembly 20 to contract. Because, the lower end of the bellows assembly 20 is attached to the cooling mass 14, when the lower end of the bellows assembly 20 moves upward, the cooling mass 14 moves upward to the second position, at which the upper surface of the cooling mass contacts a surface of the heater 11, and the lower surface of the cooling mass 14 separates from the cold manifold 32 (except for contact with the compliant link 15). As bellows assembly force is applied, pushing the cooling mass 14 into contact with the heater 11, thermally conductive contact is formed between (i) the cooling mass 14 and the heater 11, (ii) the heater 11 and the pusher 42, and (iii) the pusher 42 and the DUT. Thus, the cooling mass 14 can quickly absorb heat from the DUT via the heater 11 and the pusher 42. The pressure of the cooling mass 14 on the heater 11 also provides the contactor force to press the DUT into the electrical contacts of the contactor socket. This force may be varied by controlling the pressure in the outer chamber 22.

The heater 11 may be controlled during cold soaking to ensure that the DUT is within the temperature tolerances required to complete electronic testing. The rate of energy transfer between the cooling mass 14 and the cold manifold 32 should be lower than the allowable heater wattage. Some amount of energy transfer is needed between the cold manifold 32 and the cooling mass 14, but too much energy transfer (that is, too much heat being transferred from the heater 11 and cooling mass 14 to the gimbal piece 32a and cold manifold 32) will result in the heater 11 being unable to keep up and maintain the DUT at the set point temperature. To limit the amount of heat transferred from the cooling mass 14 to the gimbal piece 32a, but still allow some heat to be transferred by this path, the thermally conductive compliant link 15 is provided between the cooling mass 14 and the gimbal piece 32a. Thus, during the cold soak process, there is no direct thermally conductive contact between the cold manifold 32 (e.g., the gimbal piece 32a) and the cooling mass 11. In this embodiment, the thermally conductive compliant link 15 is a metal coil. The thermally conductive compliant link 15 allows the thermal masses (e.g., the cooling mass 14) to gimbal while also limiting the amount of energy transferred between the cold manifold 32 to cooling mass 14, and thus the heater 11 and DUT, during cold soak processes.

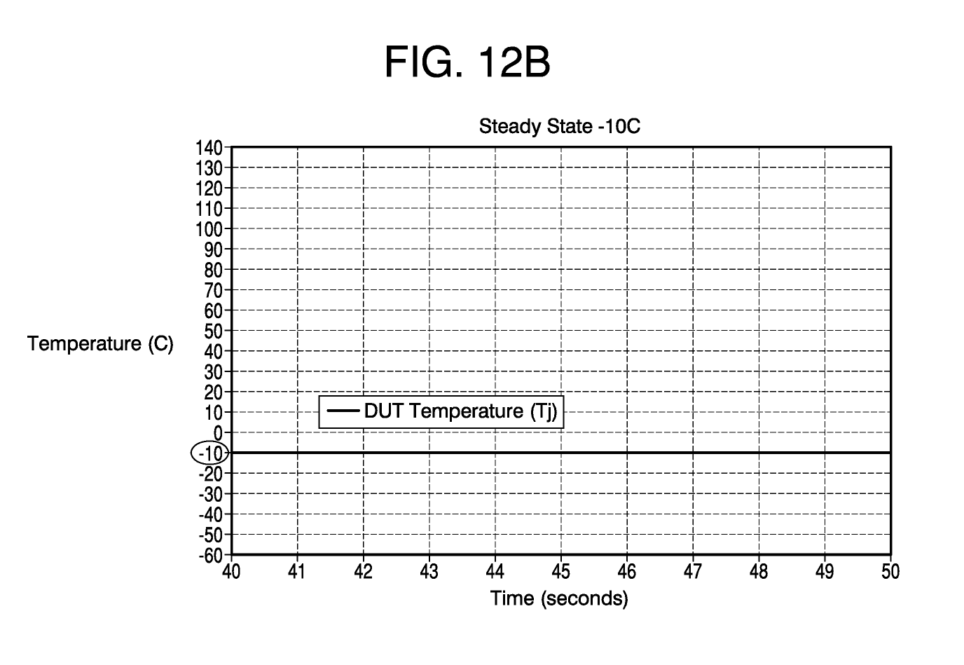

The contactor force provided by the pusher 42 on the heater 11 by the gas in the inner chamber 21 of the bellows assembly 20 during hot processes is preferably substantially equal to the contactor force provided by the pressure of the cooling mass 14 on the heater 11 during cold processes. In the embodiment shown in FIGS. 1-10, this is accomplished by using the same gas pressures in the inner and outer chamber and providing the same effective area in (i) the area defined by the seal 25, at which pressure is provided on the lower side of the heater 11, and (ii) the area of the bottom of the cooling mass 14. In other embodiments, this can be accomplished in a bellows assembly having different effective areas in the upper and lower portions by compensating for the difference using different pressures in the inner and outer chambers.

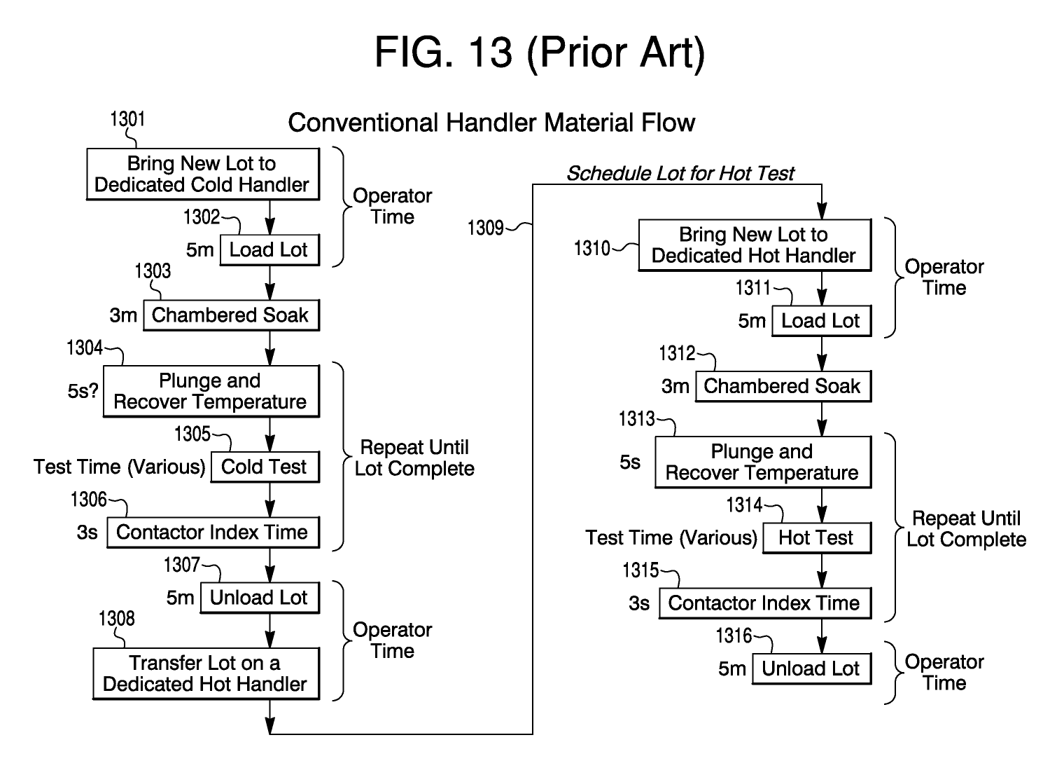

FIG. 11 is a diagram schematically showing a cold test followed by a hot test, when using a thermal head 10 of one embodiment of the invention. The thermal head 10 of the present disclosure can be used for temperature testing in a range of, for example, −40° C. to 125° C. The thermal head can adjust the temperature of a DUT from −25° C. to 90° C., and vice versa, in about 10 seconds. The thermal head 10 can adjust the temperate of a DUT from −40° C. to 125° C., and vice versa, in about 15 seconds. The thermal head 10 can maintain the temperature of a DUT within +/−1.5° C. of the set point temperature. Temperature control feedback can be performed using T_{junction}, T_{case}, T_{extrapolated}, T_{heatsink/heater} type feedback. While it is preferable to eliminate the use of a temperature chamber, a dedicated soak chamber and/or de-soak chamber may be used in combination with the above-described thermal heads.

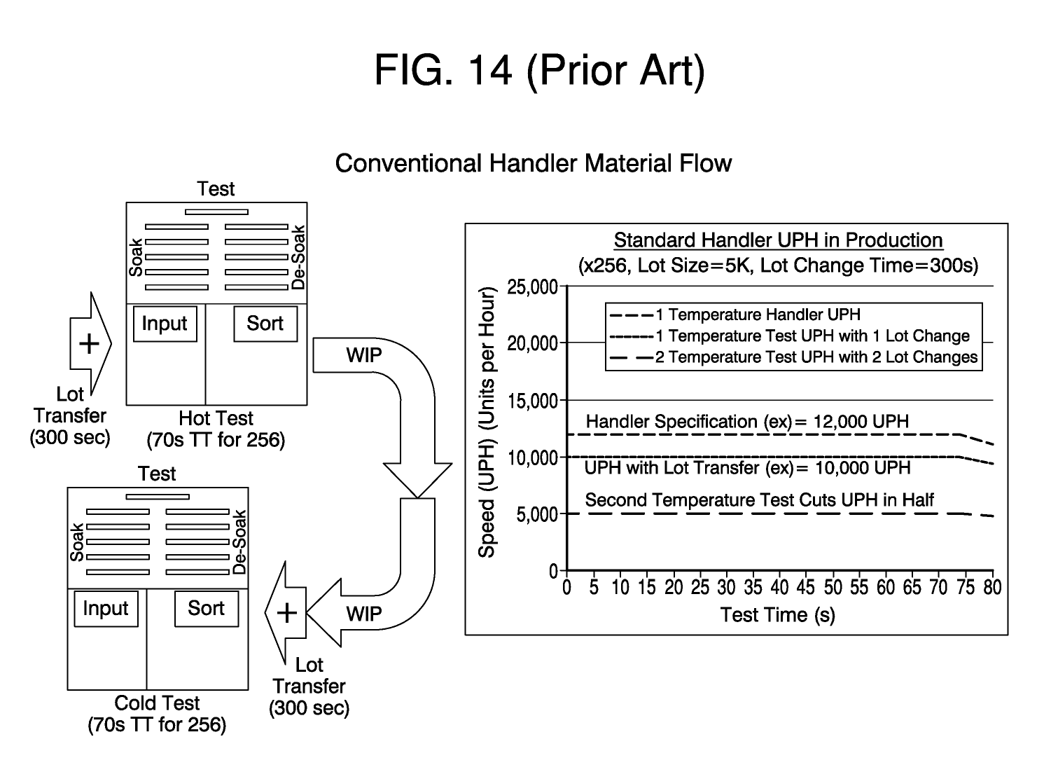

FIG. 12A-12E are graphs showing DUT temperature vs. time when using a thermal head of one embodiment of the invention, during a cold soak process (FIG. 12A), steady state at −10° C. (FIG. 12B), a hot soak process (FIG. 12C), steady state at 90° C. (FIG. 12D), and steady state at 125° C. (FIG. 12E).

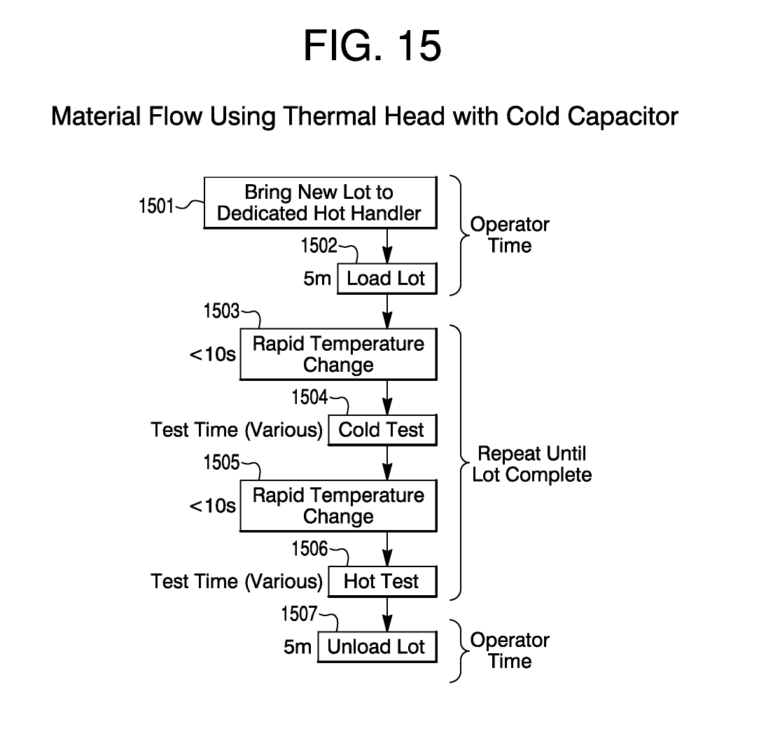

FIGS. 13 and 14 are diagrams schematically illustrating a conventional handler material flow. As shown in FIG. 13, a conventional handler material flow includes step 1301 of bringing new lot to a dedicated cold handler, step 1302 of loading the lot for 5 minutes, step 1303 of chambered soaking for 3 minutes, step 1304 of plunging and recovering temperature for about 5 seconds, step 1305 cold testing for a period of time (the period of time may vary in length), step 1306 of performing a contactor index time for 3 seconds, step 1307 of unloading the lot, step 1308 of transferring the lot on a dedicated hot handler, step 1309 of scheduling the lot for hot testing, step 1310 of brining the new lot to a dedicated hot handler, step 1311 of loading the lot from 5 minutes, step 1312 of chambered soaking for 3 minutes; step 1313 of plunging and recovering temperature for about 5 seconds. Step 1314 of hot testing for a period of time (the period of time may vary in length), step 1315 of performing a contactor index time for 3 seconds, and step 1316 of unloading the lot for 5 minutes. As shown in FIG. 14, conventional handler material flow results in a best case production speed of 5,000 units per hour (UPH), assuming two standard handlers are available and dedicated to each test temperature. The limit on the production speed is driven by the second temperature test which cuts unit production in half, relative to production without the second temperature test.

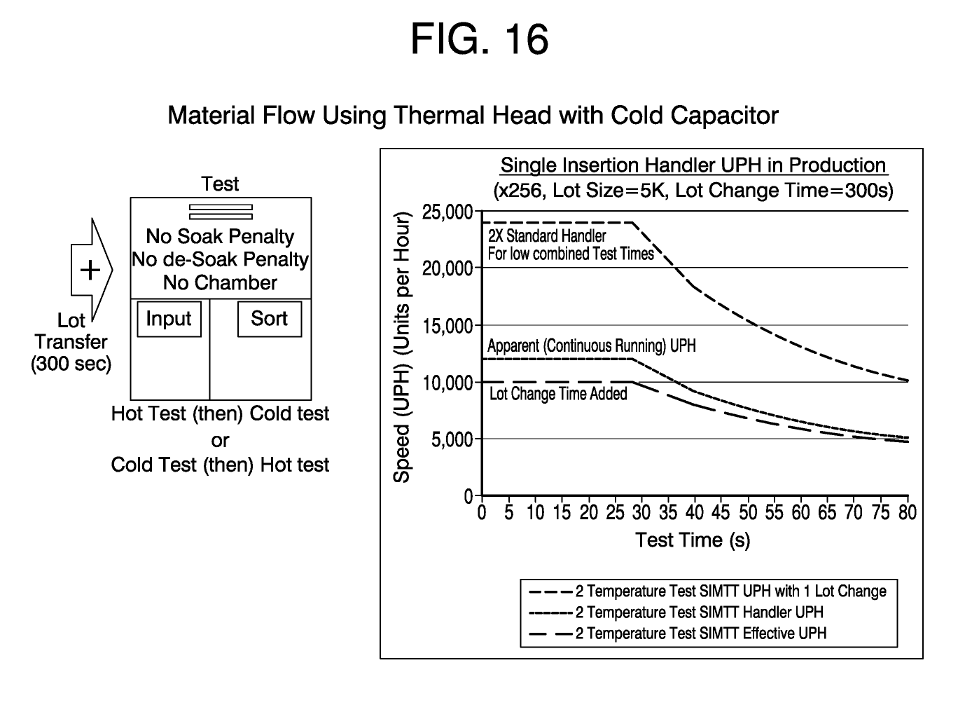

FIGS. 15 and 16 are diagraphs schematically illustrating a material flow when using a handler 100 equipped with a thermal head 10 with a cold capacitor according to an embodiment of the present invention. As shown in FIG. 15, material flow using a thermal control head with a cold capacitor includes step 1501 of bringing new lot to a dedicated hot handler, step 1502 of loading the lot for 5 minutes, step 1503 of rapidly changing temperature (e.g., changing the temperature over a time period of less than 10 seconds), step 1504 of cold testing for a period of time (the period of time may vary in length), step 1505 of rapidly changing temperature (e.g., changing the temperature over a time period of less than 10 seconds), step 1506 of hot testing for a period of time (the period of time may vary in length), and step 1507 of unloading the lot for 5 minutes. As shown in FIG. 16, this method does not have a soak penalty or a de-soak penalty and does not require chambered soaking. Additionally, this method doubles contactor life and results in a 50 percent reduction in a jam rate. As a result, this process can yield production speeds of double the production speed of conventional processes (shown in FIG. 16).

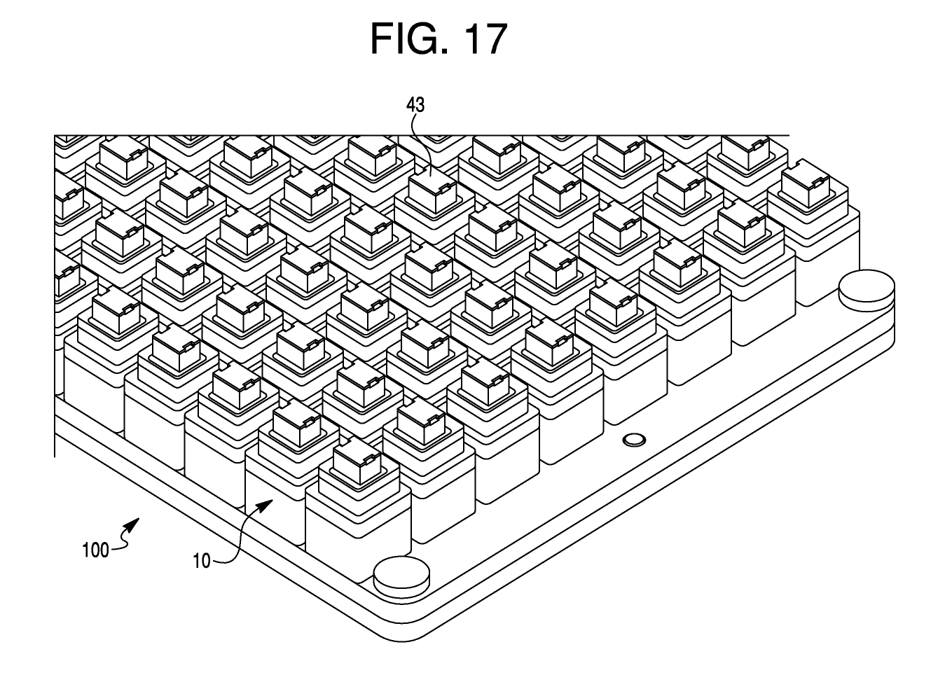

As shown in FIG. 17, a handler 100 may include a plurality of the thermal heads 10 described above with respect to FIGS. 1-10 (e.g., the handler may include 128, 256, or 512 thermal heads). Each thermal head has a DUT contact surface 43. The thermal heads 10 can be used, for example, on devices having a length and width in a range of 6 mm to 20 mm, and a minimum pitch of 27.5 mm×28.5 mm.

Embodiments of the invention allow for temperature testing to be performed at any temperature typically used during electronic device temperature testing, without the need to first prepare a temperature chamber. The amount of WIP is reduced, and the number of test trays used can be reduced by two to four times, because there is no need for additional trays to hold devices in WIP between hot and cold testing and to hold devices in a temperature chamber during soak and de-soak processes. Scheduling problems caused by using two separate dedicated hot and cold handlers can be eliminated. A 2× improvement in clearing a jam when running hot tests can be obtained, and a 30× improvement in clearing a jam when running cold tests can be obtained. The operation of additional mechanisms at ambient temperature will produce fewer jams, and reduces the need for expensive high-temperature materials.

Additionally, contactor life is doubled, because each device much be inserted into only one contactor socket for both hot and cold testing, reducing wear on contactor bushings and pogo pins/contacts. Contactor electronics are also more reliable, because the contactor can remain closer to ambient temperature due to alternating hot and cold temperature tests.

Yet another advantage of embodiments of the invention is that there is little or no temperature drop-off when a device is inserted into a contactor socket, because devices can be inserted while they are being brought to the set point temperature, and testing started only after the set point is reached. No additional temperature settling time is required.

Operator intervention can be reduced, because less time is spent loading and unloading devices, the number of jams is reduced, and the time needed to clear jams is reduced. Technician intervention is also reduced, because there are fewer repairs needed, and the cost of replacement parts is reduced.

DUT damage is also minimized, because less DUT handling is required when both hot and cold testing can be performed in the same handler.

Additionally, the thermal heads according to embodiments of the invention allow for increased compatibility with vision alignment systems. Because no temperature chamber is required, cameras, lighting, and vision electronics need not be exposed to temperature extremes. Additionally, because each device stays in the contactor for a long time (for both hot and cold testing), this increases the time available to perform vision alignment processes on the devices that will next be placed in the contactor (e.g., devices held by a pick and place device and/or devices in a test tray).

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. For example, elements shown as integrally formed may be constructed of multiple parts or elements, the position of elements may be reversed or otherwise varied, and the nature or number of discrete elements or positions may be altered or varied. The order or sequence of any process or method steps may be varied or re-sequenced according to alternative embodiments. Other substitutions, modifications, changes and omissions may also be made in the design, operating conditions and arrangement of the various exemplary embodiments without departing from the scope of the present invention.

What is claimed is:

1. A thermal control head for a semiconductor device handler, comprising:
a heater configured to heat a semiconductor device;
a cold manifold; and
a cooling mass that is movable between:
a first position at which a first surface of the cooling mass contacts a surface of the cold manifold, and
a second position at which the first surface of the cooling mass is separated from the cold manifold, and a second surface of the cooling mass contacts a surface of the heater.

2. The thermal control head of claim 1, wherein:
the cold manifold comprises a cold manifold plate and a gimbal piece that is separate from the cold manifold plate, and
when the cooling mass is in the first position, said surface of the cooling mass contacts a surface of the gimbal piece.

3. The thermal control head of claim 2, further comprising:
a thermally conductive compliant link located between the cooling mass and the gimbal piece.

4. The thermal control head of claim 3, wherein the thermally conductive compliant link is an annular coil.

5. The thermal control head of claim 4, wherein the annular coil is disposed in a groove that extends around the gimbal piece.

6. The thermal control head of claim 2, wherein at least a portion of the gimbal piece is located in a recess in a first side of the cooling mass.

7. The thermal control head of claim 2, further comprising:
a gimbal spring configured to hold a second surface of the gimbal piece against a surface of the cold manifold plate.

8. The thermal control head of claim 1, further comprising:
a heater holding plate attached to the heater in a sealed manner;
a bellows assembly that surrounds the cooling mass, wherein a first end of the bellows assembly is attached to a first end of the cooling mass in a sealed manner, a second end of the bellows assembly is attached to the heater holding plate in a sealed manner, and a first chamber is located in the bellows assembly;
an enclosure that surrounds a portion of the bellows assembly, wherein a second chamber is formed between the bellows assembly and the enclosure; and
a gas manifold comprising a first port leading to the first chamber, and a second port leading to the second chamber, wherein the gas manifold is configured to provide pressurized gas to the first chamber via the first port and to provide pressurized gas to the second chamber via the second port,
wherein, when the gas manifold provides pressurized gas to the first chamber, the cooling mass moves to the first position and the pressurized gas in the first chamber causes the second end of the bellows assembly to press the heater holding plate, and
wherein, when the gas manifold provides pressurized gas to the second chamber, the cooling mass moves to the second position.

9. The thermal control head of claim 8, wherein a first end of the enclosure is attached to the cold manifold in a sealed manner, and a second end of the enclosure is attached to the gas manifold in a sealed manner.

10. A system comprising:
the thermal control head of claim 1; and
a pusher assembly comprising:
at least one plate fixed to a stationary base,
a pusher holding plate fixed to the at least one plate, and
a pusher extending through the pusher holding plate and configured to move relative to the pusher holding plate,
wherein a first surface of the pusher is configured to be contacted by the heater, and
wherein a second surface of the pusher is configured to contact a semiconductor device under test.

11. A method of controlling a temperature of a semiconductor device using thermal control head, the method comprising:
providing a thermal control head comprising:
a heater configured to heat a semiconductor device,
a cold manifold, and
a cooling mass that is movable between:
a first position at which a first surface of the cooling mass contacts a surface of the cold manifold, and
a second position at which the first surface of the cooling mass is separated from the cold manifold, and a second surface of the cooling mass contacts a surface of the heater;
moving the cooling mass to the first position, and while the cooling mass is at the first position:
heating the semiconductor device using the heater, and
cooling the cooling mass using the cold manifold; and
moving the cooling mass to the second position, and while the cooling mass is at the second position:
cooling the semiconductor device using the cooling mass, via the heater.

12. The method of claim 11, wherein:
the cold manifold comprises a cold manifold plate and a gimbal piece that is separate from the cold manifold plate, and
when the cooling mass is in the first position, said surface of the cooling mass contacts a surface of the gimbal piece.

13. The method of claim 12, wherein:
the thermal control head further comprises a thermally conductive compliant link located between the cooling mass and the gimbal piece.

14. The method of claim 13, wherein the thermally conductive compliant link is an annular coil.

15. The method of claim 14, wherein the annular coil is disposed in a groove that extends around the gimbal piece.

16. The method of claim 12, wherein at least a portion of the gimbal piece is located in a recess in a first side of the cooling mass.

17. The method of claim 12, wherein:
the thermal control head further comprises a gimbal spring configured to hold a second surface of the gimbal piece against a surface of the cold manifold plate.

18. The method of claim 11, wherein:
the thermal control head further comprises:
a heater holding plate attached to the heater in a sealed manner;
a bellows assembly that surrounds the cooling mass, wherein a first end of the bellows assembly is attached to a first end of the cooling mass in a sealed manner, a second end of the bellows assembly is attached to the heater holding plate in a sealed manner, and a first chamber is located in the bellows assembly,
an enclosure that surrounds a portion of the bellows assembly, wherein a second chamber is formed between the bellows assembly and the enclosure, and
a gas manifold comprising a first port leading to the first chamber, and a second port leading to the second chamber, wherein the gas manifold is configured to provide pressurized gas to the first chamber via the first port and to provide pressurized gas to the second chamber via the second port, and
the cooling mass is moved to the first position by providing pressurized gas to the first chamber using the gas manifold, and while the cooling mass is in the first position, the pressurized gas in the first chamber causes the second end of the bellows assembly to press the heater holding plate, and
the cooling mass is moved to the second position by providing pressurized gas to the second chamber using the gas manifold.

19. The method of claim 18, wherein a first end of the enclosure is attached to the cold manifold in a sealed manner, and a second end of the enclosure is attached to the gas manifold in a sealed manner.

20. The method of claim 1, further comprising:
providing a pusher assembly comprising:
at least one plate fixed to a stationary base,
a pusher holding plate fixed to the at least one plate,
a pusher extending through the pusher holding plate and configured to move relative to the pusher holding plate; and
contacting a first surface of the pusher with the heater, and
contacting a semiconductor device under test with a second surface of the pusher.
